(19) United States
(12) Patent Application Publication
(10) Pub. No.: US 2007/0096778 A1
(43) Pub. Date: May 3, 2007

(54) Amplifier with passive data port for continuous VoIP

(76) Inventor: Jay F. Shapson, Englishtown, NJ (US)

Correspondence Address: Kenneth Watov;WATOV & KIPNES, P.C., P.O. Box 247, Princeton Junction, NJ, 08550, US

(21) Appl. No.: 11/520,908

(22) Filed: Sep. 14, 2006

Related U.S. Application Data
(60) Provisional application No. 60/726,574, filed on Oct. 14, 2005.

(51) Int. Cl. H03B 1/00

(52) U.S. Cl. 327/108

(57) ABSTRACT

A passive directional coupler is receptive of VoIP, Internet, and video/data signals, and is used in a CATV amplifier device to couple the video/data signals to the input terminal of an amplifier, and to bypass the VoIP and Internet signals to a modem port, for insuring continuous connection of the VoIP and Internet signals to the a modem of a user connected to the modem port, regardless of the loss of power to the amplifier or the failure of the amplifier.

### RELATED APPLICATION

The present invention is related to and takes priority from co-pending Provisional Ser. No. 60/726,574, filed on Oct. 14, 2005, the teachings of which are incorporated herein by reference to the extent they do not conflict herewith.

### FIELD OF THE INVENTION

The present invention relates generally to amplifiers, and more specifically to amplifiers for use in cable television systems.

### BACKGROUND OF THE INVENTION

A problem in present amplifiers used in cable television systems is that when there is a power outage or an amplifier otherwise becomes inoperative, the home or business user loses use of their cable modem for Internet communications. As a result, the home user will lose the use of VoIP (voice over internet protocol), and other access to the Internet. To avoid this problem bypass switching or switches have been installed in CATV systems to switch the feed cable or cable drop from the input of the amplifier directly to the input/output port of the modem. Also, relays have been used to accomplish this purpose when the amplifier loses power. There is a need in the art to improve upon present methods to maintain a home or business user's connection between their modem and the Internet in the event of an associated amplifier losing power or becoming defective.

### SUMMARY OF THE INVENTION

In one embodiment of the invention a directional coupler is built into a CATV amplifier to receive a cable drop or feed providing video/data, VoIP, and other connection to the Internet, and to couple the VoIP signals and unamplified video/data signals directly to a passive output port for connection to the modem of the user, and further couple the video/data signals to the input of the amplifier. The output of the amplifier is connected directly to a video/data active output port for one embodiment of the invention, or via a splitter to a plurality of video/data active output ports for other embodiments of the invention, for providing amplified video/data signals.

### BRIEF DESCRIPTION OF THE DRAWINGS

Various embodiments of the invention are described below with reference to the drawings, in which like elements are identified by the same reference designation, wherein:

FIG. 1A is a pictorial view of a one-output amplifier housing for one embodiment of the invention;

FIG. 1B is a block and electrical schematic diagram of the amplifier of FIG. 1A;

FIG. 2A is a pictorial view of a three-output amplifier housing for a second embodiment of the invention;

FIG. 2B is a block and electrical schematic diagram of the amplifier of FIG. 2A;

FIG. 3A is a pictorial view of an eight output amplifier housing for a third embodiment of the invention; and

FIG. 3B is a block and electrical schematic diagram of the amplifier of FIG. 3A.

### DETAILED DESCRIPTION OF THE INVENTION

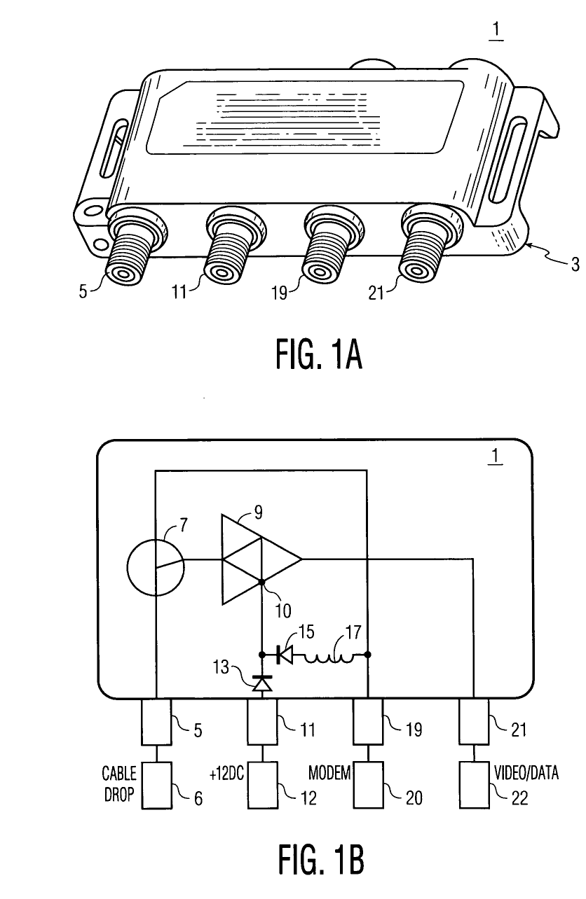

In FIG. 1A a one-output amplifier 1 having a housing 3 is shown for one embodiment of the invention. With reference to FIGS. 1A and 1B, the amplifier 1 includes an input port 5 for connection to a cable drop 6 or coaxial cable carrying video/data signals, VoIP, and Internet connection signals. Internally, the port 5 is electrically connected to a passive directional coupler 7 which partially bypasses a forward/reverse amplifier 9, and delivers or connects primary data services signals (Internet, VoIP, etc., at 2 dB down, in this example) directly to a passive modem port 19, along with unamplified video/data signals. In this manner, if there is a power interruption to the amplifier 9 or a failure in the amplifier 9 itself, there will no interruption in the primary data service connection to the modem 20 of the home or business user. In this unique manner, compliance with e911 is provided. Directional coupler 7 also delivers or connects the video/data signals to an input of amplifier 9 (at −6 dB down, in this example). A power port 11 provides for connection to a DC voltage source 12, +12 VDC, in this example. A diode 13 is connected between the port 11 and the amplifier 9, and is polarized for passing the DC voltage to a power input terminal 10 of amplifier 9. Modem port 19 is connected through an inductor 17 for blocking high frequency signals in series with a diode 15 polarized for passing a positive DC voltage to amplifier 9, if power is to be provided thereto via a power inserter connected to modem port 19 rather than by connection of a source of positive DC voltage 12 to power port 11. In this embodiment, the output of amplifier 9 is connected directly to a single active output port 21 for delivering amplified video/data signals 22 to a user.

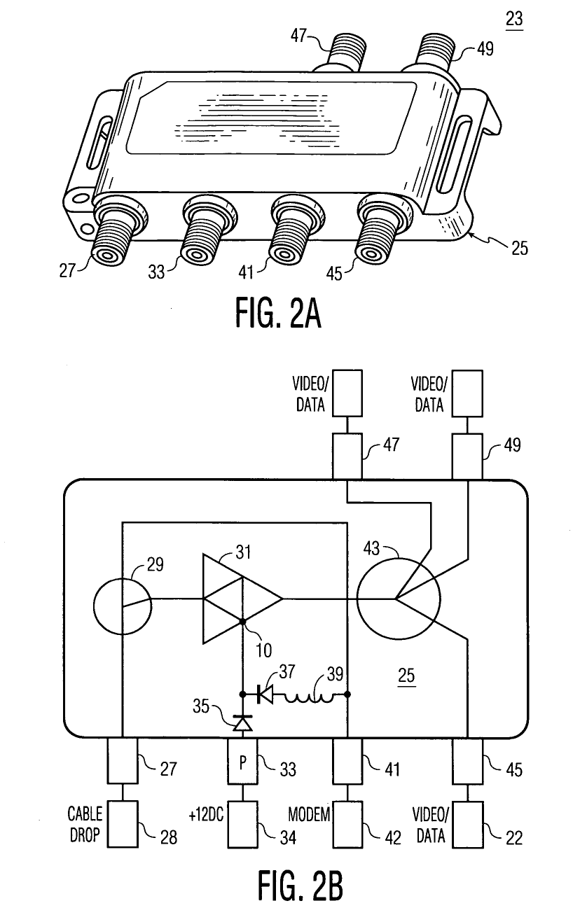

In FIG. 2A a three output amplifier device 23 having a housing 25 is shown for a second embodiment of the invention. With reference to FIGS. 2A and 2B, the amplifier device 23 includes an input port 27 for connection to a cable drop 28 or coaxial cable carrying video/data signals, and Internet connection signals. Internally, the port 27 is electrically connected to a passive directional coupler 29 which partially bypasses a forward/reverse amplifier 31, and delivers or connects primary data services (Internet, VoIP, etc., at −2 dB down, in this example) and unamplified video/data signals directly to a passive modem port 41. In this manner, if there is a power interruption to the amplifier 31 or a failure in the amplifier 31 itself, there will no interruption in the primary data service connection to the modem 42 of the home or business user. In this unique manner, compliance with e911 is provided. Directional coupler 29 also delivers or connects the video/data signals to an input of amplifier 31 (at −6 dB down, in this example). A power port 33 provides for connection to a DC voltage source 34, +12 VDC, in this example. A diode 35 is connected between the port 33 and the amplifier 31, and is polarized for passing the DC voltage to amplifier 31. Modem port 41 is connected through an inductor 39 for blocking high frequency signals in series with a diode 37 polarized for passing a positive DC voltage to amplifier 31, if power is to be provided thereto via a power inserter connected to modem port 41 rather than by connection of a source of positive DC voltage 34 to power port 33. In this embodiment, the output of amplifier 31 is connected via a splitter 43 to three active video/data output ports 45, 47, and 49, for delivering amplified video/data signals thereto. Note that the splitter 43 is a passive device.

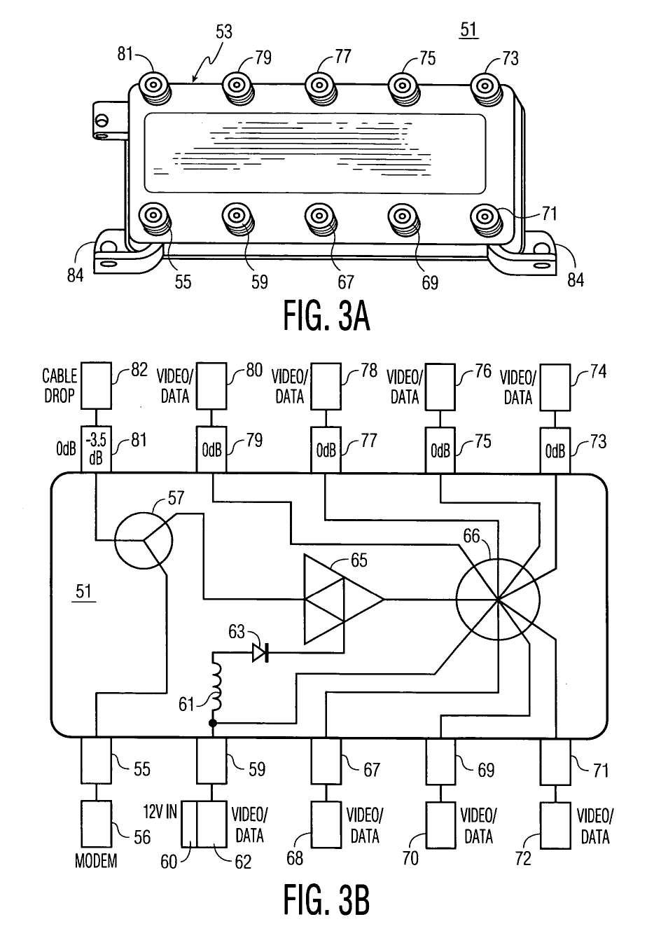

In FIG. 3A an eight output amplifier device 51 having a housing 53 is shown for a third embodiment of the invention. With reference to FIGS. 3A and 3B, the amplifier device 51 includes an input port 81 for connection to a cable drop 82 or coaxial cable carrying video/data signals, VoIP and Internet connection signals. Internally, the port 81 is electrically connected to a passive directional coupler 57 which partially bypasses a forward/reverse amplifier 65, and delivers or connects primary data services (Internet, VoIP, etc., at −3.5 dB down, in this example) and unamplified video/data signals directly to a passive modem port 55. In this manner, if there is a power interruption to the amplifier 65 or a failure in the amplifier 65 itself, there will no interruption in the primary data service connection to the modem 56 of the home or business user. In this unique manner, compliance with e911 is provided. Directional coupler 57 also delivers or connects the video/data signals to an input of amplifier 65 (at −3.5 dB down, in this example). A combined video/data output and power input port 59 provides for connection to a DC voltage source 60, +12 VDC, in this example. This video/data output and power input port 59 is connected through an inductor 61 for blocking high frequency signals in series with a diode 63 polarized for passing a positive DC voltage to amplifier 65, thereby permitting power to be provided thereto via either a power inserter or by a source 60 of positive DC voltage connected to power port 59. In this embodiment, the output of amplifier 65 is connected via a splitter 66 to eight video/data output ports 59, 67, 69, 71, 73, 75, 77, and 79, for providing amplified video/data signals 62, 68, 70, 72, 74, 76, 78, 80, and 82 thereto, respectively. Note that the splitter 66 is a passive device.

In engineering prototypes for the embodiment of the invention for FIGS. 1A and 1B, for FIGS. 2A and 2B, and for FIGS. 3A and 3B, respectively, unity gain in both the forward and reverse signal directions through the respective amplifiers 9, 31, and 65 is provided to maintain drop symmetry. Also, in the embodiment of the invention of FIG. 3A, mounting tabs 84 are provided at the corners indicated, for permitting vertical or horizontal mounting of the housing 53 of the eight output amplifier device 51. Also, in each of the aforesaid embodiments of the invention, low power integrated circuits (ICs) were utilized in order to provide a small footprint, and to reduce or minimize cooling requirements. Also, through use of surface-mount components, the associated size of the housings required were minimized, and also provided for close control of the related electrical impedances and electrical isolation, for providing a linear frequency response in either forward or reverse signal directions, respectively.

Although various embodiments of the invention have been shown and described, they are not meant to be limiting. Those of skill in the art may recognize certain modifications to the invention as taught, which modifications are meant to be covered by the spirit and scope of the appended claims. For example, in certain applications, the directional couplers can be replaced by splitters.

What I claim is:

1. An amplifier device for a cable antenna television system comprising:
an amplifier for amplifying video/data signals having an input terminal, an output terminal, and a power terminal;
at least a first video/data output port coupled to the output terminal of said amplifier;
a cable drop input terminal for receiving VoIP, Internet, video and data signals;
a power port for receiving a source of DC voltage, said power port being coupled to the power terminal of said amplifier;
a modem port for connection to the modem of a user; and
a directional coupler having an input terminal connected to said cable drop input terminal, a first output terminal for outputting said VoIP and Internet signals to the modem port, and a second output terminal for outputting video and data signals to the input terminal of said amplifier.

2. The amplifier device of claim 1, further including:
second and third video/data output ports; and
a splitter having an input connected to said output terminal of said amplifier, and first through third output terminals connected to said first through third video/data output ports, respectively, for providing amplified video/data signals thereto.

3. The amplifier device of claim 1, further including:
a first forward biased diode connected between said power port and said power terminal;
an inductor for blocking high frequency signals; and
a second forward biased diode connected in series with said inductor between said modem port and said power terminal.

4. The amplifier device of claim 2, further including:
a first forward biased diode connected between said power port and said power terminal;
an inductor for blocking high frequency signals; and
a second forward biased diode connected in series with said inductor between said modem port and said power terminal.

5. The amplifier device of claim 1, further including:
second through eighth video/data output ports; and
a splitter having an input connected to said output terminal of said amplifier, and first through eighth video/data output terminals connected to said first through eighth video/data output ports, respectively, for providing amplified video/data signals thereto.

6. The amplifier device of claim 5, further including:
a first forward biased diode connected between said power port and said power terminal;
an inductor for blocking high frequency signals; and
a second forward biased diode connected in series with said inductor between said modem port and said power terminal.

7. An amplifier device for a cable antenna television system comprising:
an amplifier for amplifying video/data signals having an input terminal, an output terminal, and a power terminal;
a plurality of video/data output ports coupled to the output terminal of said amplifier;
a cable drop input terminal for receiving VoIP, Internet, video and data signals;
a power port for receiving a source of DC voltage, said power port being coupled to the power terminal of said amplifier;
a modem port for connection to the modem of a user; and
a directional coupler having an input terminal connected to said cable drop input terminal, a first output terminal for outputting said VoIP and Internet signals to the modem port, and a second output terminal for outputting video and data signals to the input terminal of said amplifier.

8. The amplifier device of claim 7, further including:
a splitter having an input terminal connected to the output terminal of said amplifier, and a plurality of output terminals connected to the plurality of video/data output ports, respectively, for coupling amplified video/data signals thereto.

9. The amplifier device of claim 7, further including:
a first forward biased diode connected between said power port and said power terminal;
an inductor for blocking high frequency signals; and
a second forward biased diode connected in series with said inductor between said modem port and said power terminal.

10. The amplifier device of claim 8, further including:
a first forward biased diode connected between said power port and said power terminal;
an inductor for blocking high frequency signals; and
a second forward biased diode connected in series with said inductor between said modem port and said power terminal.

11. The amplifier device of claim 7, wherein said directional coupler is passive.

12. The amplifier of claim 8, wherein said directional coupler is passive.

13. The amplifier of claim 8, wherein said splitter is passive.

14. The amplifier of claim 12, wherein said splitter is passive.

15. The amplifier of claim 13, wherein said directional coupler is passive.
